(19) United States
(12) Patent Application Publication
(10) Pub. No.: US 2003/0119234 A1
(43) Pub. Date: Jun. 26, 2003

(54) Method of filling a concave portion with an insulating material

(76) Inventors: Junichi Miyano, Miyazaki (JP); Kiyohiko Toshikawa, Miyazaki (JP); Yoshikazu Motoyama, Miyazaki (JP)

Correspondence Address: VOLENTINE FRANCOS, PLLC, SUITE 150, 12200 SUNRISE VALLEY DRIVE, RESTON, VA, 20191, US

(21) Appl. No.: 10/307,280

(22) Filed: Dec. 2, 2002

Related U.S. Application Data
(63) Continuation of application No. 10/059,174, filed on Jan. 31, 2002.

(30) Foreign Application Priority Data
May 31, 2001 (JP) 163787/2001

(51) Int. Cl. H01L 21/336

(52) U.S. Cl. 438/197

(57) ABSTRACT

A method of manufacturing a semiconductor device comprises providing a substrate having a first insulating layer formed thereon. Then, a dummy layer is selectively formed on the first insulating layer. Therefore, a concave portion is formed to expose the first insulating layer. Next, a second insulating layer is selectively formed within the concave portion of the substrate. When the second insulating layer is formed, hexamethyidisilazane is used as a source gas and oxygen is used as an adjunction gas while the substrate is irradiated by vacuum ultraviolet light. By the formation of the second insulating layer, the dummy layer and the second insulating layer form an approximate flat surface.

This patent application claims priority based on a Japanese patent application, 2001-163787 filed on May 31, 2001, the contents of which are incorporated herein by reference.

### BACKGROUND OF THE INVENTION

The present invention relates to a manufacturing method suitable for manufacturing a semiconductor device having a MOSFET. More particularly, the present invention relates to a manufacturing method for an insulating film layer that can be applied to such as forming an interlayer dielectric, a conductive layer made by damascene method, a gate of FET, or an electrode of a memory capacitor.

As one of the technique for increasing an integration degree of a semiconductor device formed by the aggregation of semiconductor elements such as a MOSFET formed on the semiconductor substrate, there is a multi-level interconnection structure. The technique for forming insulating film layer, which is excellent in flatness, formed of the semiconductor element on the semiconductor substrate is extremely important to realize this multi-level interconnection structure by the photolithography-etching method.

The inventor of the present application and others proposed the method for forming an insulating film layer on an insulating film, which is formed on a semiconductor substrate, using a low pressure CVD method as described in the page 84 and 85 of the compilation of the preparatory manuscript for the general meeting of the institute of electronics, information and communication engineers held in Japan on Mar. 31, 2000.

According to this forming method of the insulating film layer, TEOS, as a source gas, and oxygen gas, as an adjunction gas, are supplied to the reaction chamber of low pressure CVD apparatus in which a semiconductor substrate, on which an insulating film layer is to be grown, is arranged. Then, a good insulating film layer can be formed by irradiating a vacuum ultraviolet light on the insulating film layer of a semiconductor substrate.

### SUMMARY OF THE INVENTION

The present invention may provide a method for suitably and profitably manufacturing a semiconductor device including a method that can form a further high-quality insulating film layer.

Moreover, the present invention may provide al method that can form an insulating layer having excellent planarization characteristic by suitably embedding a concave portion. The concave portion is formed by a protruding portion or a dummy layer formed on the semiconductor substrate.

The present invention is based or, the basic conception of using hexamethyldisilazane, (CH₃)₃SiOSi(CH₃)₃ as a source gas for a process of forming an insulating film layer on the selected region of the semiconductor substrate using low pressure CVD method.

A method of manufacturing a semiconductor device according to the present invention comprises providing a substrate having a first insulating layer formed thereon. Then, a dummy layer is selectively formed on the first insulating layer. Therefore, a concave portion is formed to expose the first insulating layer. Next, a second insulating layer is selectively formed within the concave portion of the substrate. When the second insulating layer is formed, hexamethyldisilazane is used as a source gas and oxygen is used as an adjunction gas while the substrate is irradiated by vacuum ultraviolet light. By the formation of the second insulating layer, the dummy layer and the second insulating layer form an approximate flat surface.

### BRIEF DESCRIPTION OF THE DRAWINGS

FIG. 1 shows a rough cross sectional view of a CVD apparatus that performs the manufacturing method according to the present invention.

FIG. 2 is a graph that shows a result of FTIR analysis for an insulating film layer according to the present invention formed using HMDSO as a source gas.

FIG. 3(a) to FIG. 3(c) show a manufacturing process of an example that applies the manufacturing method according to the present invention to form an interlayer dielectric.

FIG. 4 is a graph that shows a result of FTIR analysis for an insulating film layer according to the present invention formed using TEOS as a source gas.

FIG. 5(a) to FIG. 5(e) show a manufacturing process of an example that applies the manufacturing method according to the present invention to a damascene process for conductive layer.

FIG. 6(a) to FIG. 6(d) show a manufacturing process of an example that applies the manufacturing method according to the present invention to a dual damascene process for two-layer conductive layer.

FIG. 7(a) to FIG. 7(d) show a second example of a manufacturing process that applies the manufacturing method according to the present invention to a dual damascene process for two-layer conductive layer.

FIG. 8 shows a cross section of an example that applies the manufacturing method according to the present invention to a forming process of a gate of FET.

FIG. 9 shows a cross section of an example that applies the manufacturing method according to the present invention to a forming process of a contact hole of FET.

FIG. 10 shows a cross section of an example that applies the manufacturing method according to the present invention to a forming process of a capacitor electrode of a memory cell.

### DETAILED DESCRIPTION OF THE PREFERRED EMBODIMENTS

The invention will now be described based on the preferred embodiments shown by the figures.

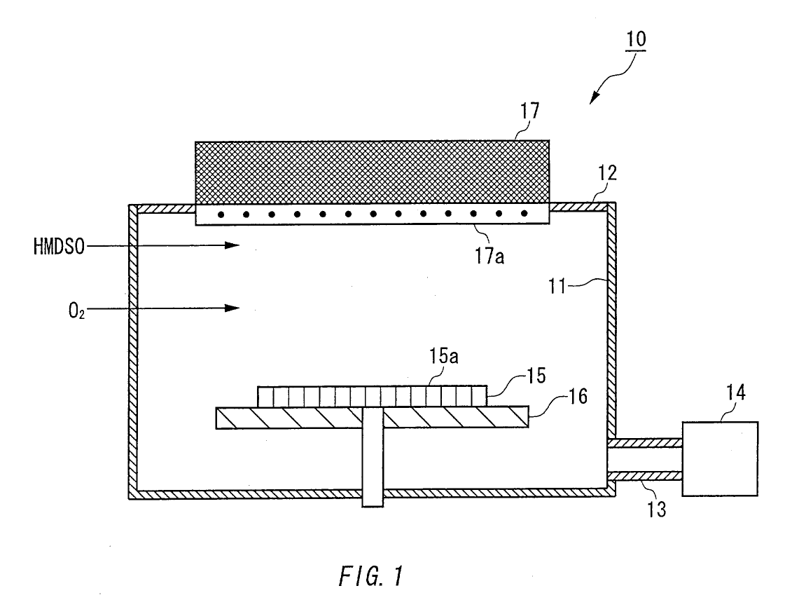

FIG. 1 shows a rough view of low pressure CVD apparatus for performing a manufacturing method according to the present invention. The low pressure CVD apparatus 10 is used in the case of forming an insulating film layer such as silicon oxide film on a semiconductor substrate.

As shown in FIG. 1, the low pressure CVD apparatus 10 comprises a pipe-shaped housing 12 that covers whole of the reaction chamber 11, a negative pressure source 14 made of such as vacuum pump connected through a piping 13 to one end of the housing 12 to maintain inside the reaction chamber 11 to a decompression state, a susceptor 16 for holding a semiconductor wafer 15 made of such as silicon inside the reaction chamber 11, and a vacuum ultraviolet light source 17 such as an xenon excimer lamp. As a vacuum ultraviolet light source 17, a light source that generates ultraviolet light in a so-called vacuum ultraviolet region, the wavelength of which is shorter than about 200 nm, can be suitably selected.

The semiconductor wafer 15 is held on the susceptor 16 so that the silicon oxide film 15a formed on the surface of the semiconductor wafer 15 faces upwardly. The temperature of the semiconductor wafer 15 can be adjusted between room temperature and 350° C. by the temperature adjustment of the susceptor 16.

The vacuum ultraviolet light source 17 has a quart window 17a that becomes an irradiation window, on which a synthesis quart board having a thickness of 20 mm, for example, is mounted. The housing 12 supports this quart window 17a so that the quarts window 17a locates on the upper side of the semiconductor wafer 15. The vacuum ultraviolet light is irradiated to the silicon oxide film 15a of the semiconductor wafer 15 through the quart window 17a.

In the manufacturing method according to the present embodiment, hexamethyldisilazane, (CH₃)₃SiOSi(CH₃)₃, simply called as HMDSO in the following, is introduced inside the reaction chamber 11 as a raw material gas, and oxygen, O₂, is introduced inside the reaction chamber 11 as adjunction gas to grow an insulating film layer on the silicon oxide film 15a, which is formed on a semiconductor wafer 15.

The experiment to confirm the effect of the present invention will be explained. The semiconductor wafer 15, on the surface of which the silicon oxide film 15a was formed, was maintain in a room temperature on the susceptor 16. The distance between the semiconductor wafer 15 and the quart window 17a of the vacuum ultraviolet light source 17 was maintained to about 15 mm. The semiconductor wafer 15 was irradiated by the vacuum ultraviolet so that the illuminance of the vacuum ultraviolet light became 10 mW/cm₂ at right under the quart window 17a. Under this circumferences, the HMDSO of 50 sccm and the oxygen of 50 sccm, which was same flow amount with the HMDSO, are supplied inside the reaction chamber 11. The reaction pressure inside the reaction chamber 11 at this time was 600 mTorr.

It is desirable to heat this quarts window 17a to temperature that exceeds the temperature of the vacuum ultraviolet source so as to prevent clouds occurred on the quarts window caused by the growth of the insulating film layer on the quarts window 17a, which is described later.

The low pressure CVD apparatus 10 was operated for about 10 minutes under the condition described above. An insulating film layer having a thickness of about 5000 Å, the main component of which is silicon dioxide, was grown on the silicon oxide film 15a of the semiconductor wafer 15.

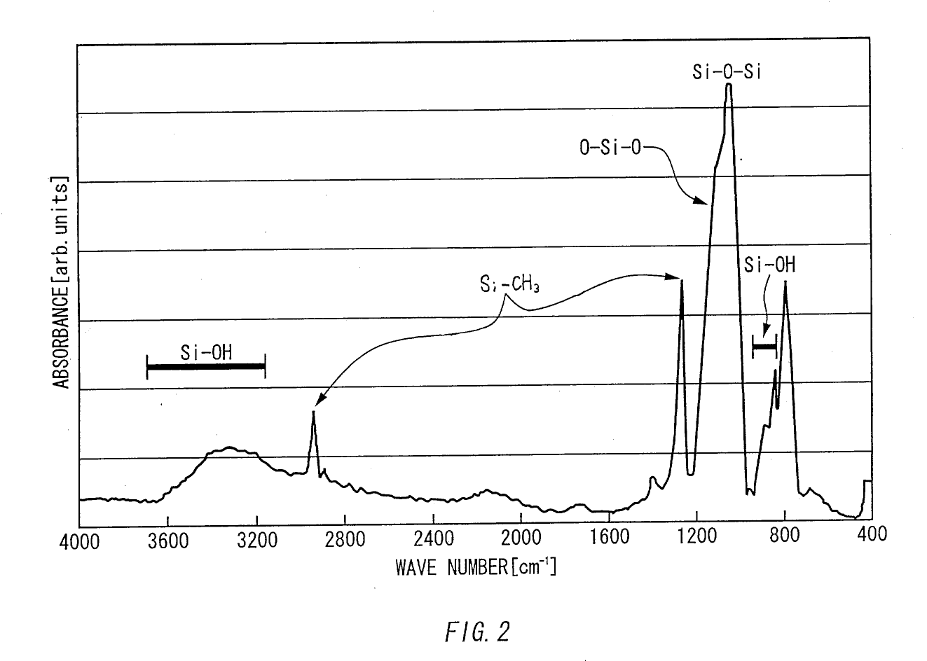

FIG. 2 is a graph that shows a result of analysis that analyzes the components of the insulating film layer using a Fourier transform infrared spectroscopy.

The horizontal axis of the graph shows an inverted number of wavelengths, that is, wave number (cm⁻¹), of the infrared light irradiated to the insulating film layer, which is a sample, and the vertical axis of the graph shows an absorbance, the unit of which is arbitrary.

According to the Fourier transform infrared spectroscopy, the infrared light of each wavelength corresponding to each material, which is irradiated by the infrared light, is absorbed with the high absorbance when the wavelength of the infrared light, which is irradiated to the sample, is continuously shifted. Therefore, the component of that material can be known by obtaining the wave number, at which the absorbance increases sharply.

According to the analyzed results shown in FIG. 2, as shown in the graph, silicon monoxide (Si₂O), SiOH, and SiCH₃ are formed in addition to the silicon dioxide (SiO₂), which is a main component. Any one of these shows an electrical insulating characteristic, and especially SiCH₃ is an organic material that shows lower permittivity than that of the silicon dioxide, which is a main component. Therefore, it has an excellent electrical characteristic as an interlayer dielectric material of a semiconductor device.

Furthermore, the insulating film layer formed by the method according to the present embodiment has excellent flatness. Therefore, photolithography etching can be accurately performed on the insulating film layer, and it can thus be applied to the various manufacturing process of the semiconductor device.

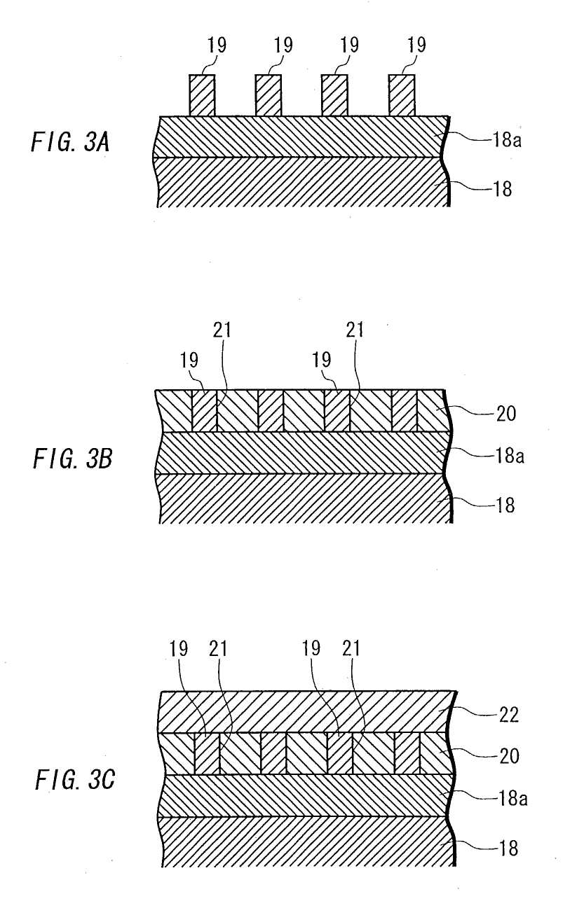

FIG. 3(a) to FIG. 3(c) shows an example of utilizing the manufacturing method according to the present invention for manufacturing an inter layer dielectric of a semiconductor device.

In the manufacturing process of the semiconductor device having MOS transistor, as shown in FIG. 3(a), a plurality of conductive patterns 19 are formed on the silicon semiconductor substrate 18, for example. A circuit element, not shown in the figure, such as MOS transistor is formed on the semiconductor substrate 18. The conductive layer 19 is formed on the insulating film 18a having a thickness of 5000 Å such as silicon oxide film on the silicon semiconductor substrate 18 for these circuit elements on the silicon semiconductor substrate 18.

The conductive layer 19 is configured by the metal material, for example such as tungsten or Al—Si—Cu alloy, as conventionally well known. Each conductive patterns 19 have a thickness of 0.5 μm and width of 0.3 μm, for example. Each conductive patters 19 extend such that they are arranged parallel to each other with, for example, 0.5 μm interval in its width direction.

By arranging the semiconductor substrate 18, on which the conductive pattern 19 is formed, on the susceptor 16 of the low pressure CVD apparatus 10 shown in FIG. 1 such that the conductive patterns 19 face upward direction by and growing the insulating film layer, which is described above, under the same condition as described above, the insulating film layer 20 that has the same components with that of shown in FIG. 2 which includes SiCH₃ and silicon dioxide as main component can be selectively grown on the region where the conductive patterns 19 are not formed on the insulating film 18a as shown in FIG. 3(b).

The insulating film layer 20 is intensively deposited on the part where the insulating film 18a is exposed, that is, the concave part 21 formed between the conductive patterns 19. Therefore, the insulating film layer 20 is grown selectively on the insulating film 18a. This insulating film layer 20 is grown until the upper face of the insulating film layer 20 matches to the upper face of the conductive patterns 19 as shown in FIG. 3(b) by about 10 minutes of growth.

Because the insulating film layer 20 shows an extremely high flatness characteristic, the conductive patterns 19 and the insulating film layer 20 that fill between the conductive patterns 19 as a whole forms a flat film. Therefore, there is no need for applying an etching back process to the insulating film layer 20 by such as a chemical mechanical polishing (CMP) or plasma dry etching process to obtain a flat face described above. For example, the interlayer dielectric 22 having a flat surface can be formed such that it covers the conductive patterns 19, which are the protruding parts, and the insulating film layer 20, which is filled between the conductive patterns 19, as shown in FIG. 3(c) by depositing new insulating material having a thickness of 3000 Å.

The deposition of the new insulating material 22 is enabled by cutting the supply of oxygen and by supplying only HMDSO under the irradiation of the vacuum ultraviolet light inside the low pressure CVD apparatus 10.

Moreover, instead of the above-mentioned method, each methods of a plasma enhanced CVD (PECVD), a low pressure CVD (LPCVD), an atmospheric CVD (APCVD), which are conventionally well known, can be used appropriately to form the interlayer dielectric 22.

The good filling effect of the concave part 21 by the insulating film layer 20 is recognized in the range where the distance between the protruding part 19 described above is from 0.3 to 0.7 μm.

As described above, by the method according to the present invention, the exposed parts of the insulating film 18a formed on the semiconductor substrate 18, which is the concave part 21 formed by the protrude part 19, can be properly filled by the insulating film layer 20. Thereby, the flat interlayer dielectric 22 can be grown without applying the etching back process. Therefore, the manufacturing process of the semiconductor device can be simplified, and the production cost can be reduced.

It was confirmed that the phenomenon, in which the exposed part of the insulating film 18a formed on the semiconductor substrate 18 can be filled properly by the insulating film layer as same as above, can also be realized by using tetraethylorthosilicate (Si(OC₂H₅)₄: simply called as FEOS in the following) instead of HMDSO as a source gas in the method using the low pressure CVD apparatus 10 shown in FIG. 1.

In this manufacturing method using this TEOS, the TEOS of, for example 50 sccm, and the oxygen of 50 sccm, which was the same flow amount with that of the TEOS, were supplied inside the reaction chamber 11. The reaction pressure inside the reaction chamber 11 at this time was 600 mTorr as same as in the HMDSO. Moreover, the illuminance of the vacuum ultraviolet light irradiated from the vacuum ultraviolet light source 17 was 10 mW/cm² at right under the quart window 17a.

In the example using this TEOS, the distance between the semiconductor wafer 15 supported on the susceptor 16 and the quarts window 17a of the vacuum ultraviolet light source 17 was maintained to about 100 mm. Furthermore, the quarts window 17a was heated so that the temperature right under the quarts window 17a is maintained to 200° C.

Under the growing condition that uses TEOS, the insulating film layer, which had a silicon dioxide as main component and has thickness of about 5000 Å, was selectively deposited on the exposed parts of the insulating film 18a formed on the semiconductor substrate 18 similar to that of shown in FIG. 3(a)-3(c) for 30 minutes.

By this selective growth of this insulating film layer mentioned above, the flat face was formed by the protrude parts 19 and the insulating film layers 20 that were filled between the concave parts 21 as shown in FIG. 3(b). By forming the interlayer dielectric 22, which is similar to that of shown in FIG. 3(c), on this flat face, a flat interlayer dielectric 22 could be formed without performing the etching back process.

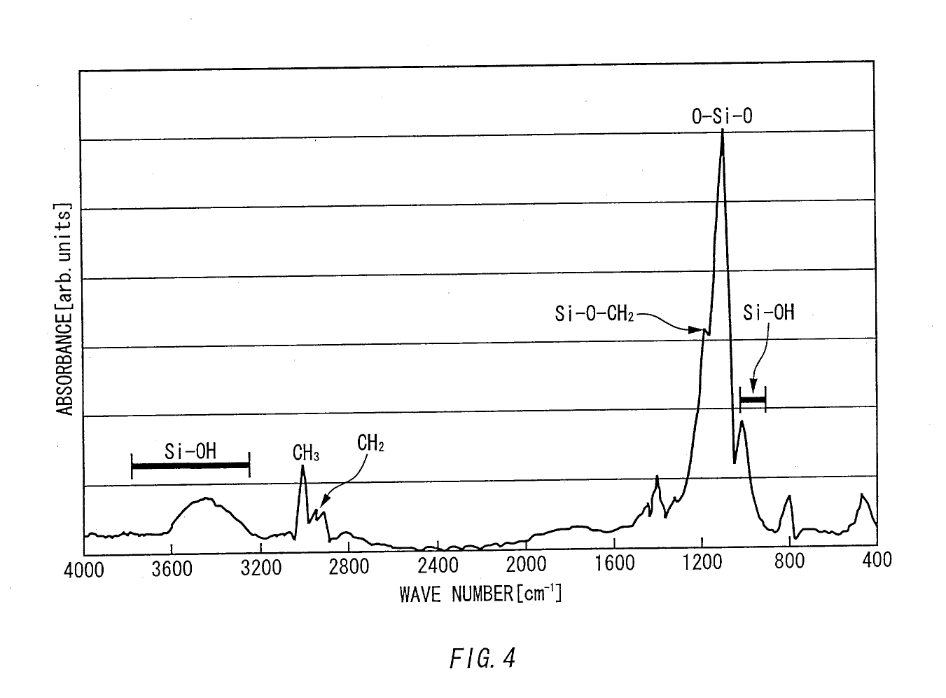

FIG. 4 is a graph similar to FIG. 2 that shows the result of analyzing the component of the insulating film layer 20 formed by the method using TEOS as source.

According to the graph sh!own in FIG. 4, organic SiOCH₂, which shows lower permittivity than silicon dioxide is formed in addition to silicon dioxide (Si₂O), which is main component. Therefore, the insulating film layer 20 according to the present invention formed using TEOS as a source gas has an excellent electric characteristic as an interlayer dielectric of the semiconductor device. Furthermore, the insulating film layer 20 according to the present invention formed using TEOS as source gas has excellent flatness as same as the insulating film layer 20 according to the present invention that is formed using HMDSO as source gas.

The method using HMDSO and TEOS can be used for various semiconductor manufacturing process by using above-mentioned selective growth characteristic.

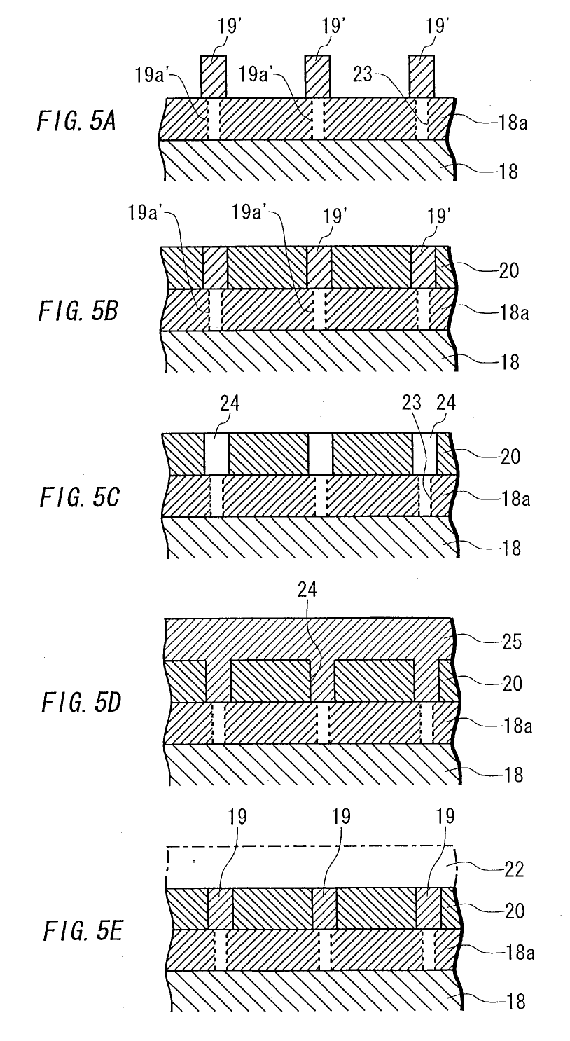

FIG. 5(a)-FIG. 5(e) shows an example that uses the method according to the present invention to a damascene process.

As shown in FIG. 5(a), the insulating film 18a is formed on the semiconductor substrate 18. A plurality of dummy pattern 19′, which is comprised of the photoresist material that includes such as organic material for forming the conductive patterns 19, are formed on the insulating film 18a. Each dummy patterns 19′ has, for example, width of 0.5 μm and height of 0.5 μm and extends such that each dummy patterns 19′ is arranged parallel to each other with an 0.1 μm interval, for example.

To form these dummy patterns 19′, the photoresist material having photo-sensitiveness is applied over the insulating film 18a to a substantially uniform thickness as similar to forming the conventional photoresist pattern. The photoresist layer formed by applying the photoresist material is selectively exposed using a desired photo mask, and then the exposed photoresist layer is developed. The dummy pattern 19′ having a desired shape is formed by the selective exposure of the photoresist material using this photomask and a lithography technique including developing process. As a photoresist for this dummy pattern 19′, any one of a positive type or a negative type can be selected according to the necessity.

Furthermore, before applying the photoresist material on the insulating film 18a, a hole 23 having diameter of, for example, 0.3 μm as a contact hole can be formed in the insulating film 18a according to the necessity. The photolithographiy-etching technique can be used for this forming of the hole 23 in the insulating film 18a. In this case, the photoresist material is applied on the insulating film 18a to fill inside the hole 23. The dummy pattern 19′ is also formed in the contact part 19a′ that reaches to the upper face of the semiconductor substrate 18 through the hole 23.

After forming the dummy patterns 19′, as shown in FIG. 5(b), the insulating film layer 20 having a thickness substantially matches to that of the dummy pattern 19′ is grown to fill the space between the dummy patterns 19′ that constitutes protrude part by the method according to the present invention that uses HMDSO or TEOS.

This insulating film layer 20 is selectively deposited in the concave parts between the dummy patterns 19′ and is not deposited on the dummy pattern 19′ as described above. By this selective growth, the flat face is formed by the insulating film layer 20 and the dummy pattern 19′ as shown in FIG. 5(b).

Then, the photoresist material that constitutes dummy patterns 19′ is removed by such as fuming nitric acid, organic parting agent, or oxygen plasma. By this removal of the photoresist material, as shown in FIG. 5(c), the dummy patterns 19′ are removed (together with the contact part 19a′) from the semiconductor substrate 18, and by this removal, concave portions 24 that correspond to dummy pattern 19′ (and the contact part 19a′) are formed in the insulating film layer 20.

After removing the photoresist material, the concave portion 24 is filled with the conductive material 25 such as copper by the plating method that uses cupric sulfate solution, for example. This conductive material 25 fills the concave portion 24 that includes the part that corresponds to the contact part 19a′. The conductive material 25 is also deposited on the insulating film layer 20 with a thickness of about 7000 Å as shown in FIG. 5(d).

After forming the conductive material 25, by removing the unnecessary conductive material 25 on the insulating film layer 20 by such as CMP method to expose the surface of the insulating film layer 20, the conductive pattern 19 embedded in this insulating film layer 20 is formed.

As shown in FIG. 5(e), the interlayer dielectric 22 as described above is formed on the insulating film layer 20 to cover this conductive pattern 19. Furthermore, an upper conductive layer is formed on the interlayer dielectric 22 according to necessity.

According to the method according to the present invention, the insulating film layer 20 that fills the space existed between the dummy patterns 19′ formed by the photoresist material can be grown under the room temperature environment by the irradiation of the vacuum ultraviolet light. Because the dummy patterns 19′ is not exposed to high temperature, the method can prevent the melting or burning of the dummy pattern 19′ itself by the heating of this dummy pattern 19′. Thus, the realization of the damascene conductive layer with high accuracy becomes possible.

Moreover, because the insulating film layer 20 is deposited between the dummy patterns 19′ with high flatness, there is no need for performing the planarization process such as an etching back for this insulating film layer 20. Therefore, it becomes possible to simplify the manufacturing process.

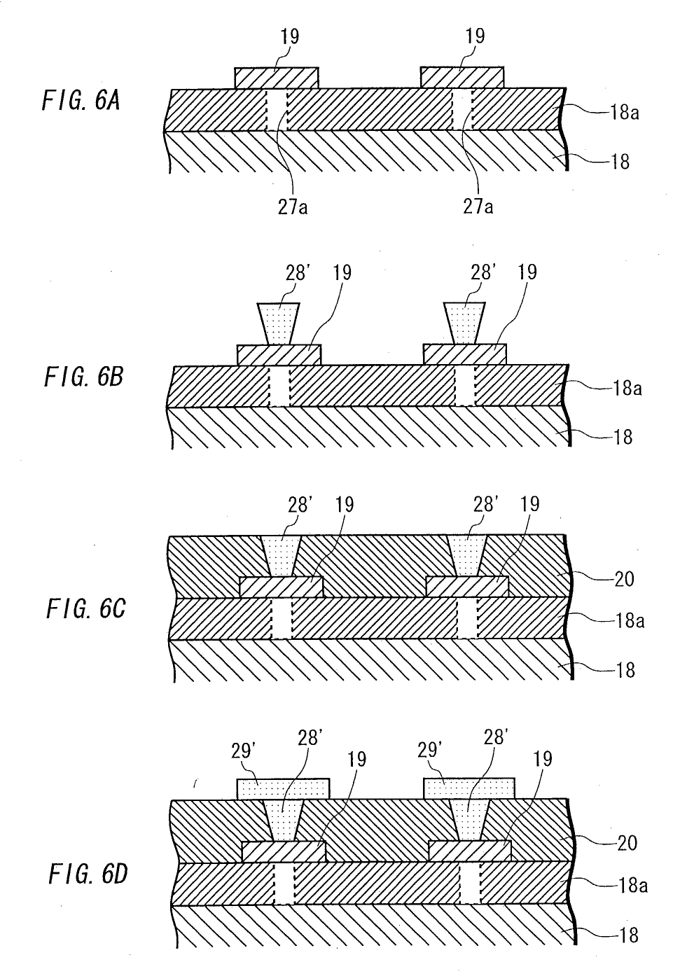

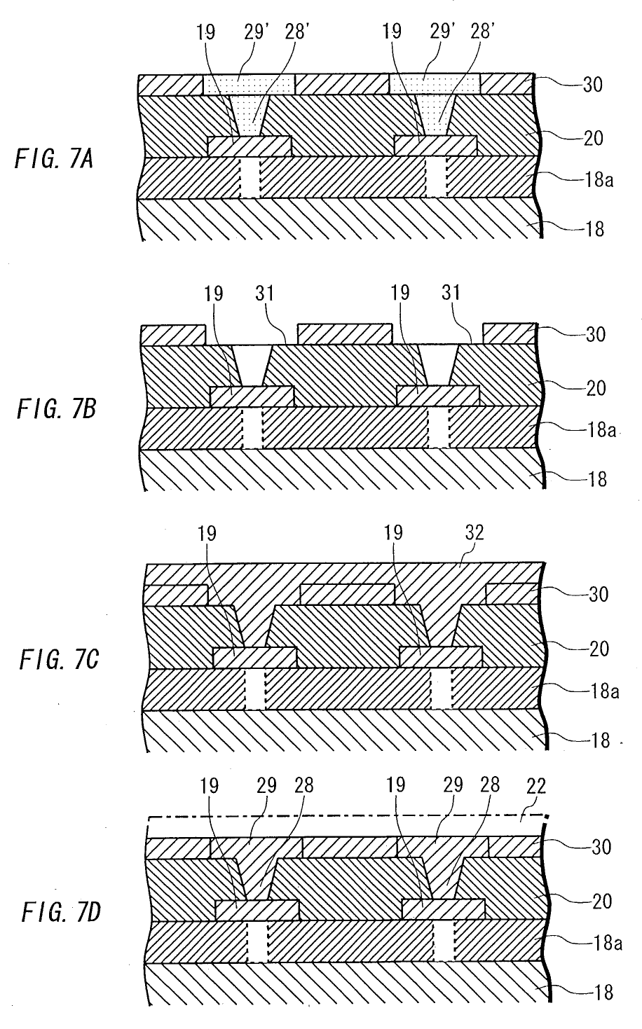

FIG. 6(a)-FIG. 6(d) and FIG. 7(a)-FIG. 7(d) show examples that use the method according to the present invention for the dual damascene process.

As shown in FIG. 6(a), an insulating film 18a having a thickness of, for example, 5000 Å is formed on the semiconductor substrate 18. The conductive patterns 19 same as that of explained in FIG. 3 having a thickness of, for example, 3000 Å are formed on the insulating film. These conductive patterns 19 are connected to desired part of the semiconductor substrate 18 through the contact holes 27a formed in the insulating film 18a in accordance with necessity.

As shown in FIG. 6(b), a column part 28′ made of the photoresist material, is formed on the desired part of each of the conductive patterns 19 as same as described in FIG. 5. Each column parts 28′ made of the photoresist material, that is, first dummy patterns 28′ have height of, for example, 5000 Å and have reversed tapered shape, the diameter of tip of which decreases from its upper end to lower end.

After forming the first dummy pattern 28′, as described in FIG. 5(b), the insulating film layer 20 having a thickness substantially matches to that of the first dummy pattern 28′ is grown to fill the space between the first dummy patterns 28′ and the conductive pattern 19 that constitutes protrude parts by the method according to the present invention that uses HMDSO or TEOS.

This insulating film layer 20 is selectively deposited in the concave parts between the protrude parts and is not deposited on the first dummy pattern 28′ as described above. By this selective growth, the flat face is formed by the insulating film layer 20 and the first dummy pattern 28′ as shown in FIG. 6(c).

Furthermore, as shown in FIG. 6(d), protrude parts made of the photoresist material that passes the first dummy pattern 28′ and are also parallel to the conductive patterns 19, that is, the second dummy patterns 29′ for upper conductive layer are formed on the insulating film layer 20 by the lithography technique as described above. The second dummy pattern 29′ has thickness of, for example, 5000 Å. It is desirable to clean the upper surface of the first dummy pattern 28′ using fluorine plasma or rare oxygen fluoride to remove a silica film that attached to the upper face of the first dummy pattern 28′ before forming the second dummy pattern 29′.

After forming the second dummy pattern 29′, as shown in FIG. 7(a), the insulating film layer 30, which is similar to the insulating film layer 20, is grown on the insulating film layer 20 to fill the spaces between the second dummy pattern 29′ by the method according to the present invention.

This new insulating film layer 30 is deposited until the height of which substantially matches to the upper surface of the second dummy pattern 29′, which is a column part. Then, the first dummy pattern 28′ and the second dummy pattern 29′ are removed by the method as same as that of explained in FIG. 5(c). Thereby, as shown in FIG. 7(b), through-hole that exposes the conductive pattern 19 and the concave portion 31 that is a groove for an upper conductive layer are formed inside the insulating film layer 20 and 30.

After removing the first dummy pattern 28′ and the second dummy pattern 29′ made of the photoresist material, the concave portion 31 is filled with the conductive material 32 such as copper by the plating method that uses above-mentioned cupric sulfate solution. This conductive material 32 fills the concave portion 31 that includes the part that corresponds to the column part 29a′. The conductive material 32 is formed on the insulating film layer 30 with a thickness of about 7000 Å as shown in FIG. 7(c).

After forming the conductive material 32, the surface of the insulating film layer 30 is exposed by removing the unnecessary conductive material 32 on the insulating film layer 30 by such as CMP method. Thereby, a double conductive layer structure, which has an upper conductive layer 29 formed by the conductive material 25 and a contact part 28 that connects the upper conducive layer to the lower conductive layer 19, are formed under these insulating film layer 30 and the insulating film layer 20 by the damascene method.

As shown in FIG. 7(d), the interlayer dielectric 22 as described above is formed on the insulating film layer 30 to cover the double conductive layer structure.

By the method according to the present invention, the insulating film layer 20 and 30 that fills the space existed between the first dummy pattern 28′ and the second dummy pattern 29′ made of the photoresist material can be grown under the room temperature environment by the irradiation of the vacuum ultraviolet light. Therefore, the dummy pattern does not expose under the high temperature. That is, the method can prevent the melting or burning of the first dummy pattern 28′ and the second dummy pattern 29′ themselves by the heating of the first dummy pattern 28′ and the second dummy pattern 29′. Thus, the realization of the dual damascene conductive layer with high accuracy becomes possible.

Moreover, because each of the insulating film layer 20 and 30 are deposited between the first dummy pattern 28′ and the second dummy pattern 29′ with high flatness, there is no need for performing the process such as an etching back on these insulating film layer 20 and 30. Therefore, it becomes possible to simplify the manufacturing process.

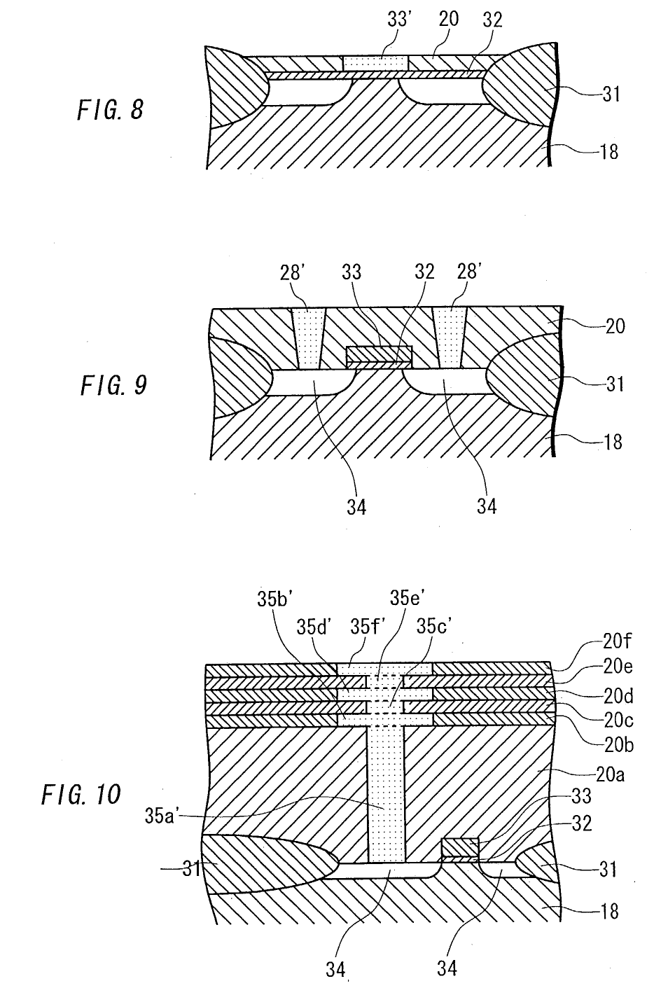

FIG. 8 shows an example that applies the method according to the present invention to a gate forming process of a MOS transistor, which is one of an FET, field-effect transistor. A field oxide film 31 is formed on the semiconductor substrate 18 by such as the LOCOS method, which is conventionally well known, as shown in FIG. 8. A gate oxide film 32 made of silicon dioxide is formed on the active region, which is divided by the field oxide film 31 of the semiconductor substrate 18 by such as thermal oxidation method.

A dummy 33′ for a gate is formed on the gate oxide film 32 by the photosensitive photoresist material, which includes organic component, using lithography technique as described above. This dummy 33′ for a gate has a thickness of, for example, 3000 Å and width of 0.18 μm.

After forming the dummy 33′ on the field oxide film 31, as shown in FIG. 8, the insulating film layer 20 is grown on the gate oxide film 32, on which the dummy 33′ that constitutes protrude part is formed, until the thickness of insulating film layer 20 substantially matches to the thickness of the dummy 33′, which is about 3000 Å, by the method according to the present invention that uses HMDSO or TEOS, as described above.

Because this insulating film layer 20 is not deposited on the dummy 33′, which is a protrude part, as described above, a flat face is formed by the insulating film layer 20 and dummy 33′ by this selective growth.

Then, the dummy 33′ made of the photoresist material is removed by such as fuming nitric acid, organic parting agent, or oxygen plasma as the example described above. A conductive material such as polycrystalliine silicon for a gate 33 (referring to FIG. 9) is filled in the concave part, which is formed by this removal of the photoresist material, by such as the LPCVD method, and the unnecessary conductive material deposited on the insulating film layer 20 is removed by such as the CMP method.

After that, the part of the interlayer dielectric 22 that surrounds the gate 33 and the unnecessary part that is exposed from the gate 33 of the gate oxide film 32 are removed. Thereby, the gate 33 for a MOS transistor is formed.

Instead of removing the above-mentioned unnecessary conductive material on the insulating film layer 20, a conductive pattern can be formed using the conductive material on the insulating film layer 20 by performing a patterning on the conductive material deposited on the insulating film layer 20 by the photolithography-etching technique.

By applying the method according to the present invention, the insulating film layer 20 that embeds the dummy 33′ made of the photoresist material can be grown under the room temperature environment by the irradiation of the vacuum ultraviolet light. Because the dummy is not exposed to high temperature, the method can prevent the melting or burning of the dummy 33′ by the heating of this dummy 33′. Thus, the gate can be formed with high accuracy.

Moreover, because good flat face can be obtained by the insulating film layer 20 that embeds dummy 33′, there is no need for performing the particular planarization process such as an etching back on this insulating film layer 20. Therefore, it becomes possible to simplify the manufacturing process.

FIG. 9 shows an example that applies the method according to the present invention to the forming process of the contact hole that is performed successively after the gate forming process of a MOS transistor.

After forming the gate 33 that is explained according to FIG. 8, as shown in FIG. 9, the source-drain regions 34 are formed on the both sides of the gate 33 by injecting impurity to the semiconductor substrate 18 by such as an ion implantation.

After forming the source-drain region 34, the dummy 28′ for the contact part, which is to be built-up from now, is formed on each of the regions by the photosensitive photoresist material that includes organic material using the lithography technique as same as discussed above. The dummy 28′ for this contact part has a height of, for example, 5000 Å and diameter of 0.5 μm.

After forming the dummy 28′ on each of the source-drain regions 34, as shown in FIG. 9, the insulating film layer 20 is grown on the semiconductor substrate 18, on which the dummy 28′ that constitutes protrude part is formed, until the thickness of the insulating film layer 20 substantially matches to that of the dummy 28′ by the method according to the present invention that uses HMDSO or TEOS, as described above.

Because this insulating film layer 20 is not deposited on the dummy 28′, which is a protrude part, as described above, a flat face is formed by the insulating film layer 20 and dummy 28′ by this selective growth.

After that, the dummy 28′ made of the photoresist material is removed as same as the above-mentioned example, and a conductive material such as polycrystalline silicon, Al—Si—Cu alloy, or cooper for a contact part is filled in the concave part, which is formed by this removal of the photoresist material, by such as the LPCVD method. By removing the unnecessary conductive material deposited on the insulating film layer 20 by such as the CMP method, a contact part that reaches to each source-drain regions 34 is formed.

After that, the unnecessary part of the conductive material deposited on the interlayer dielectric 22 is removed. As described above, by performing a patterning on the conductive material deposited on the insulating film layer 20, a conductive pattern can be formed using the conductive material on the insulating film layer 20.

By applying the method according to the present invention to the forming of the contact hole, the insulating film layer 20 that embeds the dummy 28′ made of the photoresist material can be grown under the room temperature environment by the irradiation of the vacuum ultraviolet light. Because the dummy is not exposed to high temperature, the method can prevent the melting or burning of the dummy 28′ by the heating of this dummy 28′. Thus, the contact hole can be formed with high accuracy.

Moreover, because the insulating film layer 20 that embeds dummy 28′ shows good flatness as described above, good flat face can be obtained by properly growing this insulating film layer to the height of the dummy 28′. Therefore, there is no need for performing the particular planarization process such as an etching back on this insulating film layer 20. Thus, it becomes possible to simplify the manufacturing process.

FIG. 10 shows an example that applies the present invention to the forming process of the capacitor of a memory cell such as DRAM.

As shown in FIG. 10, an active region, which is formed by the field oxide film 31, is formed on the semiconductor substrate 18, and the gate 33 as same as described above is formed on this active region, and then the source-drain region 34 is formed. After forming the MOS transistor that comprise the gate 33 and the source-drain region 34, a capacitor that uses the MOS transistor as a switching element is formed.

Before forming this capacitor, as shown in FIG. 10, a dummy 35a′ for a contact part, which is built-up from the source-drain region 34, is formed on one of the source-drain region 34 using the photosensitive photoresist material that includes organic material by the lithography technique as same as discussed above. The dummy 35a′ for this contact part has a height of, for example, 5000 Å and diameter of 0.18 μm.

After forming this dummy 35a′, the insulating film layer 20a is grown until the thickness of the insulating film layer 20 substantially matches to that of the dummy 35a′, which is a protrude part, by the method according to the present invention that uses HMDSO or TEOS, as described above.

Because the insulating film layer 20a is not deposited on the dummy 35a′, which is a protrude part, as described above, a flat face is formed by the insulating film layer 20a and the dummy 35a′ by this selective growth.

Next, a dummy 35b′ having a diameter increased part that has a diameter of, for example, 0.3 μm that is about two times of the diameter of the dummy 35b′ and has a height of, for example, 2000 Å is formed on the dummy 35a′ by the lithography technique for the photosensitive photoresist material that includes organic component.

It is desirable to clean the upper surface of the dummy 35b′ using fluorine plasma or rare oxygen fluoride to remove a silica film that attached to the upper face of the dummy before forming the dummy 35b′.

After forming the dummy 35a′ that forms a contact part and the dummy 35b′ that forms the diameter increased part, the insulating film layer 20b is again grown on the insulating film layer 20a until the thickness of the insulating film layer 20b substantially matches to that of the dummy 35b′ to embed the diameter increased part by the method according to the present invention, as described above.

Furthermore, a dummy 35c′ made of the photoresist material, which forms a diameter decreased part that has a substantially same diameter with that of dummy 35a′ and has a height of about 2000 Å, is formed on the dummy 35b′, which is a diameter increased part, by the process as same as described above.

These dummies 35b′, 35d′, and 35f′ that forms diameter increased parts, and the dummies 35c′ and 35e′ that forms diameter decreased parts are formed alternatively by repeating the process as described above, and corresponding to that, new insulating film layers 20b, 20c, 20d, 20e, and 20f, which embed each of the diameter increased parts 35b′, 35d′, 35f, and the diameter decreased part 35e′ and 35e′, are deposited one after another on the insulating film layer 20a.

After forming the insulating film layer 20a-20f, each of which embeds the dummies 35a′-35f′ made of the photoresist material, the dummies 35a′-35f′ made of the photoresist material, is removed by such as fuming nitric acid, organic parting agent, or oxygen plasma as same as the example described above. A conductive material as described above is filled in the concave part, which is formed by the removal of this photoresist material, by such as the LPCVD method as same as the example described above, and the unnecessary conductive material deposited on the insulating film layer 20f is removed by such as the CMP method.

After that, the insulating film layers 20b, 20c, 20d, and 20e are removed using, for example, rare fluorine oxygen, and thereby, one side of electrode made of a conductive material comprising a plurality of fin parts corresponding to the dummies 35b′, 35c′, 35d′, 35e′, and 35f′ are exposed. A high-dielectric constant film such as silicon nitride film having a thickness of, for example, 100 Å is formed on the surface of this exposed electrode by such as the LPCVD method. Furthermore, another electrode made of polycrystalline silicon is formed such that another electrode covers the high-dielectric constant film by such as the LPCVD method.

By applying the method according to the present invention to the forming of the electrode of the memory cell, the insulating film layers 20a-20f that embed the dummies 35a′-35f′ made of the photoresist material can be grown under the room temperature environment by the irradiation of the vacuum ultraviolet light. Because the dummy is not exposed to high temperature, the method can prevent the melting or burning dummies 35a′-35f′ by the heating of these dummies 35a′-35f′. Thus, the one side of the electrode of the capacitor can be formed with high accuracy corresponding to the dummies 35a′-35f′.

Moreover, because good flatness can be obtained by the insulating film layer 20a-20f that embeds dummies 35a′-35f′ one after another as described above, there is no need for performing the particular planarization process such as an etching back to each of insulating film layers 20a-20f, and it thus becomes possible to simplify the manufacturing process.

According to the present invention, a high quality insulating film layer that shows low permittivity favorable as an interlayer dielectric can be formed by supplying HMDSO (hexamethyidisilazane) as a source gas and oxygen as adjunction gas inside the reaction chamber under the condition where the vacuum ultraviolet light is irradiated on the semiconductor substrate inside the reaction chamber of the low pressure CVD apparatus as described above.

Furthermore, under the above-mentioned growth condition, the insulating film layer can be selectively grown in the concave part region, which is a region excluding the protrude part, by previously forming the protrude part on the semiconductor substrate by the photoresist material or the conductive material, for example. Therefore, the method of the present invention can be applied to the various manufacturing process of the semiconductor device such as an interlayer dielectric of the semiconductor device, a gate, a damascene conductive layer, and an electrode of memory capacitor.

Furthermore, for the selective growth of the insulating film layer in the concave part region, the concave part region can be embed by the insulating film layer that shows good flatness characteristic with using the TEOS (tetraethylorthosilicate) instead of the HMDSO as source gas. Thereby, an insulating film layer, which is high quality and has excellent planarization characteristic, can be formed as same as in the case of using the HMDSO.

What is claimed is:

1. A method of filling a concave portion comprising:
providing a substrate having a concave portion thereon;
providing the substrate in a chamber of an LPCVD apparatus; and
introducing a hexamethyidisilazane gas and an oxygen gas to said chamber while irradiating vacuum ultraviolet light to the substrate so as to form an insulating layer in the concave portion of the substrate.

2. A method of filling a concave portion according to claim 1, wherein said concave portion is formed by a protrude made of a conductive material.

3. A method of filling a concave portion according to claim 1, wherein the insulating layer is selectively formed in the concave portion.

4. A method of filling a concave portion according to claim 1, wherein the insulating layer has a substantial planer surface.

5. A method of filling a concave portion according to claim 4, further comprising:
forming another insulating layer on the substantial planer surface of the insulating layer.

6. A method of filling a concave portion according to claim 1, wherein the concave portion is for a gate of a transistor.

7. A method of filling a concave portion according to claim 1, wherein the concave portion is for a contact hole formed on a source/drain region of a transistor.

8. A method of filling a concave portion according to claim 1, wherein the concave portion is for a capacitor electrode.

9. A method for manufacturing a semiconductor device comprising:
providing a semiconductor substrate;
forming a first insulating layer on the substrate;
selectively forming a dummy layer on the first insulating layer so as to form a concave portion exposing the first insulating layer;
selectively forming a second insulating layer on the exposed first insulating layer by a chemical vapor deposition using hexamethyldisilazane as a source gas and oxygen as an adjunction gas while the substrate is irradiated by vacuum ultraviolet light.

10. A method for manufacturing a semiconductor device according to claim 9, wherein the dummy layer and the second insulating layer form a substantial planer surface.

11. A method for manufacturing a semiconductor device according to claim 9, wherein the first insulating layer has a through hole exposing the substrate and wherein the dummy layer is formed on the through hole.

12. A method for manufacturing a semiconductor device according to claim 11, further comprising:
removing the dummy layer so as to form a contact hole exposing the substrate, the contact hole passing through the first and second insulating layers;
depositing a conductive material on the second insulating layer so that the contact hole is filled with the conductive material; and
chemically and mechanically polishing the deposited conductive material until the second insulating layer is exposed so that the conductive material is remained within the contact hole.

13. A method for manufacturing a semiconductor device according to claim 9, wherein the chemical vapor deposition is performed at a room temperature.

14. A method for manufacturing a semiconductor device according to claim 9, wherein flow rates of the source gas and the adjunction gas are substantially same.

15. A method for manufacturing a semiconductor device according to claim 9, wherein the chemical vapor deposition is performed under pressure of about 600 mTorr.

16. A method of manufacturing a semiconductor device comprising:
providing a substrate having a first insulating layer formed thereon;
selectively forming a dummy layer on the first insulating layer so as to form a concave portion exposing the first insulating layer;
selectively forming a second insulating layer within the concave portion of the substrate using hexamethyidisilazane as a source gas and oxygen as an adjunction gas while the substrate is irradiated by vacuum ultraviolet light so that the dummy layer and the second insulating layer form an approximate flat surface.

17. A method of manufacturing a semiconductor device according to claim 16, wherein a conductive pattern is formed on and through the first insulating layer so that the conductive pattern is electrically connected to the substrate and wherein the dummy layer is formed on the conductive pattern.

18. A method of manufacturing a semiconductor device according to claim 17, further comprising:
removing the dummy layer so as to form a contact hole exposing the conductive pattern, the contact hole passing through the second insulating layer;
depositing a conductive material on the second insulating layer so that the contact hole is filled with the conductive material; and
chemically and mechanically polishing the deposited conductive material until the second insulating layer is exposed so that the conductive material is remained within the contact hole.

19. A method of manufacturing a semiconductor device according to claim 16, wherein the insulating film is formed at a room temperature.

20. A method for manufacturing a semiconductor device according to claim 16, wherein flow rates of the source gas and the adjunction gas are substantially same.
